(19) United States
(12) Patent Application Publication
(10) Pub. No.: US 2012/0217234 A1
(43) Pub. Date: Aug. 30, 2012

(54) KINETIC SPRAYED RESISTORS

(75) Inventors: Richard C. Abbott, Boucherville (CA); Pierre Marcoux, Beloeil (CA)

(73) Assignee: THERMOCERAMIX INC., Boucherville (CA)

(21) Appl. No.: 13/158,951

(22) Filed: Jun. 13, 2011

Related U.S. Application Data
(60) Provisional application No. 61/353,977, filed on Jun. 11, 2010.

(51) Int. Cl. H05B 3/10; H05K 13/00

(52) U.S. Cl. 219/552; 29/611

(57) ABSTRACT

A method of fabricating a kinetic-sprayed resistor for use in a heater, the method including kinetic spraying a powder in a pattern on an electrically-insulating substrate to create a resistive coating on the substrate in the pattern. A kinetic-sprayed resistor for use in a heater having been fabricated via the aforementioned method. A heater including the aforementioned kinetic-sprayed resistor, wherein the resistor is connectable to a power source to generate heat when electrical current runs through the resistor.

### CROSS-REFERENCE TO RELATED APPLICATIONS

The present application claims the benefit of priority to U.S. provisional patent application Ser. No. 61/353,977, filed Jun. 11, 2010, entitled “Kinetic Sprayed Resistors”. This application is incorporated by reference herein in its entirety.

### FIELD OF THE INVENTION

The present invention relates to sprayed resistors, particularly kinetic sprayed resistors.

### BACKGROUND

Sprayed resistors, are, as their name suggests, resistors that have been sprayed on an (electrically-insulating) substrate to create a layer that can serve as a heat source when an electrical current is passed through the layer.

U.S. Pat. No. 6,762,396, issued Jul. 13, 2004, entitled “Deposited Resistive Coatings” (incorporated herein by reference in its entirety), describes such a sprayed resistor having been created via an arc plasma spraying procedure. As is described therein “[a] coating, in the form of a resistive heating layer of this invention, comprises at least one material, preferably a low-density ceramic that possesses the following qualities: an ability to withstand high temperatures, a resistance to oxidation, and a low mass for rapid temperature response to voltage inputs. The resistive heating layer is also highly refractory so that a fairly high power density is achievable.” (Col. 3, Lines 44-50). . . . “In another preferred embodiment, the resistive heating layer is composed of a mixture of at least two materials, one material being electroconductive (low resistivity) and the other material being insulating (high resistivity). The overall resistivity of the resistive heating layer is controlled by blending the materials prior to deposition in such proportions that, when they are deposited as a coating by, for example, arc plasma spraying, the desired resistivity is obtained.” (Col. 3, Lines 59-67).

An improvement over the '396 patent is described in U.S. Pat. No. 6,919,543, issued Jul. 19, 2005, entitled “Resistive Heaters and Uses Thereof” (incorporated herein by reference in its entirety). As is described therein, the inventors state that they “have discovered a metallic resistive layer (and methods of making same) that includes a metallic component that is electroconductive and an oxide, nitride, carbide, and/or boride derivative of the metal component that is electrically insulating.” (Col. 5, Line 65 to Col. 6, Line 3). . . . “In the present invention, the resistivity is controlled in part by controlling the amount of oxide, nitride, carbide, and boride formation during the deposition of the metallic component and the derivative.” (Col. 6, Lines 24-27). . . . “Metallic components of the invention include any metals or metalloids that are capable of reacting with a gas to form a carbide, oxide, nitride, boride, or combination thereof. Exemplary metallic components include, without limitation, transition metals such as titanium (Ti), vanadium (V), cobalt (Co), nickel (Ni), and transition metal alloys; highly reactive metals such as magnesium (Mg), zirconium (Zr), hafnium (Hf), and aluminum (Al); refractory metals such as tungsten (W), molybdenum (Mo), and tantalum (Ta); metal composites such as aluminum/aluminum oxide and cobalt/tungsten carbide; and metalloids such as silicon (Si). These metallic components typically have a resistivity in the range of 1−100×10⁻⁸Ω·m. During the coating process (e.g., thermal spraying), a feedstock (e.g., powder, wire, or solid bar) of the metallic component is melted to produce, e.g., droplets and exposed to a gas containing oxygen, nitrogen, carbon, and/or boron. This exposure allows the molten metallic component to react with the gas to produce an oxide, nitride, carbide, or boride derivative, or combination thereof, on at least a portion of the surface of the droplet.” (Col. 6, Lines 43-62). “The nature of the reacted metallic component is dependent on the amount and nature of the gas used in the deposition. For example, use of pure oxygen results in an oxide of the metallic component. In addition, a mixture of oxygen, nitrogen, and carbon dioxide results in a mixture of oxide, nitride, and carbide. The exact proportion of each depends on intrinsic properties of the metallic component and on the proportion of oxygen, nitrogen, and carbon in the gas. The resistivity of the layers produced by the methods herein range from 500-50,000 10⁻⁸ Ω·m.” (Col. 6, Line 63 to Col. 7, Line 5). “In order to obtain oxides, nitrides, carbides, or borides of a metallic component, the gas that is reacted with the component must contain oxygen, nitrogen, carbon, and/or boron. Exemplary gases include oxygen, nitrogen, carbon dioxide, boron trichloride, ammonia, methane, and diborane.” (Col. 7, Lines 15-19). . . . “The resistive layers and other layers of a coating of the present invention are desirably deposited using a thermal spray apparatus. Exemplary thermal spray apparatuses include, without limitation, arc plasma, flame spray, Rockide systems, arc wire, and high velocity oxy-fuel (HVOF) systems.” (Col 7, Lines 22-27).

Using the thermal spray technique to make resistive coatings for use with heaters is not, however, without its drawbacks. For one, a single thermal spray operation will not generally result in forming a resistive coating layer having the required thickness (to create the amount of material required to provide the required amount of heat). Thus, when using thermal spray, several layers are usually required to be deposited one on top of the other, to form an overall coating layer having the required thickness. Secondly, masks are also required to be placed over the substrate to be sprayed in order to define where the sprayed material is to be deposited on the substrate. This is because the distribution of the material output from the thermal spray gun is not narrow and confined but rather generally broad Gaussian. Thirdly, coatings having been deposited via thermal spray tend to curl and delaminate due to residual tensile stresses. As a consequence of these drawbacks improvement would be desirable.

Kinetic spray (sometimes also known as “cold spray”) is also a well-known technique to deposit material on a surface. It is conventionally generally used to deposit materials on a substrate where minimum oxidization of the coating and substrate is desired. (Which, as was discussed above, has not typically been the case when forming resistive coating layers for heaters.) Kinetic spray is a material coating method in which solid-state powders (of between 1 to 50 micrometers in diameter) are accelerated in supersonic gas jets to velocities up to 500-1000 m/s. During impact with the substrate, particles undergo plastic deformation and bond to the surface. Metals, polymers, and composite materials can be deposited using kinetic spray.

Kinetic sprayed materials have several important properties. Particularly, the deposited material is subject to minimum oxidation, it is very dense, it typically manifests residual compressive stress, and the adhesion strength is very high. Kinetic spray operations can operate with a high material deposition rate, which is generally desirable in a manufacturing context (and generally means that only one operation may be required to deposit the required amount of material). The kinetic spay material stream can be very well defined such that masks (on the substrate) are not needed during material deposition; the width of the material deposited is based on the width of the output from the kinetic spray gun nozzle. Kinetic spray is, however, limited to materials with some ductility since temperatures are typically not elevated during kinetic spray operations to a level at which the material being sprayed becomes highly plastic or molten (as is the case in thermal spray operations). Kinetically sprayed particles deform upon impact with the substrate because of the conversion of their kinetic energy. Therefore, kinetic spray materials are almost never purely ceramic (as they would shatter as opposed to simply deform).

Given the advantages of kinetic spray, using a kinetic spray operation instead of thermal spray operation would be desirable for fabricating resistive coatings for use in heaters (as it would overcome some of the drawbacks of using thermal spray). However, unlike thermal spray, kinetic spray operations do not have the inherent property of oxidizing the material via heating in an atmosphere having at least some partial pressure of oxygen (which is now conventional in creating resistive coatings via thermal spray operations).

It is therefore desirable to adapt the kinetic spray process for use in such applications.

### SUMMARY

It is an object of the present invention to ameliorate at least some of the inconveniences present in the prior art.

Thus, in one aspect, as embodied and broadly described herein, some embodiments of the present invention provide a method of fabricating a kinetic-sprayed resistor for use in a heater, comprising: selecting a metal powder with a resistivity between 10⁻⁵ Ohm-cm and 10⁻³ Ohm-cm; oxidizing the metal powder to create a predetermined molar fraction of metal oxide; and kinetic spraying the oxidized metal powder in a pattern on an electrically-insulating substrate to create a resistive coating on the substrate in the pattern.

In some of such embodiments the method further comprises coupling at least one electrical connector to the resistive coating.

In some of such embodiments, the oxidizing of the metal powder is performed for a pre-determined length of time and at a pre-determined temperature.

In some of such embodiments, the metal powder comprises at least one metal selected from a group consisting of copper, nickel, titanium, aluminum, nickel-chromium, nickel alloys, iron, iron-chromium-aluminum, iron alloys, tungsten, molybdenum, and platinum.

In some of such embodiments, the oxidizing includes thermally spraying the metal powder in an atmosphere having a partial pressure of oxygen.

In some of such embodiments, the partial pressure of oxygen in the atmosphere is controlled by having a predetermined amount of oxygen in the atmosphere.

In another aspect, as embodied and broadly described herein, some embodiments of the present invention provide a method of fabricating a kinetic-sprayed resistor for use in a heater, comprising: providing a mixture of ceramic powder and metal powder having a predetermined bulk resistivity; and kinetic spraying the mixture of ceramic powder and metal powder in a pattern on an electrically-insulating substrate to create a resistive coating on the substrate in the pattern.

In some of such embodiments, the method further comprises coupling at least one electrical connector to the resistive coating.

In some of such embodiments, the metal power comprises at least one metal selected from a group consisting of CrC₂—NiCr and WC—Co.

In another aspect, as embodied and broadly described herein, some embodiments of the present invention provide a method of fabricating a kinetic-sprayed resistor for use in a heater, comprising: agglomerating an electrically-insulating powder and a metallic powder to create an agglomerated powder having a predetermined bulk resistivity; and kinetic spraying the agglomerated powder in a pattern on a electrically-insulating substrate to create a resistive coating in the pattern on the substrate.

In some of such embodiments, the method further comprises coupling at least one electrical connector to the resistive coating.

In another aspect, as a embodied and broadly described herein, some embodiments of the present invention provide a method of fabricating a kinetic-sprayed resistor for use in a heater, wherein a predetermined amount of heat is generated when a predetermined electrical current at a predetermined voltage is passed through the resistor, the method comprising: selecting (i) a metal powder having a resistivity between 10⁻⁵ Ohm-cm and 10⁻³ Ohm-cm and (ii) a pattern including a width, a length, and a thickness, such that when the metal powder is kinetically-sprayed in the pattern onto an electrically-insulating substrate, a coating layer is formed such that when the predetermined electrical current at the predetermined voltage is passed through the resistor the predetermined amount of heat is generated; and kinetic spraying the metal powder in the pattern on the electrically-insulating substrate to create the resistive coating in the pattern on the substrate.

In some of such embodiments, the method further comprises coupling at least one electrical connector to the resistive coating.

In some of such embodiments, the metal powder comprises a metal alloy.

In some embodiments of more than one of the aforementioned aspects, the resistive coating sprayed in the pattern forms one selected from a group consisting of circuits in series, circuits in parallel, and a combination of circuits in series and circuits in parallel.

In some embodiments of more than one of the aforementioned aspects, at least one of a width and a height of the resistive coating sprayed in the pattern varies to result in temperature varying across the resistor when an electrical current is sent through the resistive coating.

In some embodiments of more than one of the aforementioned aspects, the pattern includes at least one bus and at least one of a width and a thickness of the resistive coating is greater at the bus.

In a further aspect, as embodied and broadly described herein, some embodiments of the present invention provide a kinetic-sprayed resistor for use in a heater having been fabricated via one of aforementioned methods.

In a further aspect, as embodied and broadly described herein, some embodiments of the present invention provide a heater including a kinetic-sprayed resistor having been fabricated via one of the aforementioned methods, wherein the resistor is connectable to a power source to generate heat when electrical current runs through the resistor.

Embodiments of the present invention each have at least one of the above-mentioned object and/or aspects, but do not necessarily have all of them. It should be understood that some aspects of the present invention that have resulted from attempting to attain the above-mentioned object may not satisfy this object and/or may satisfy other objects not specifically recited herein.

Additional and/or alternative features, aspects, and advantages of embodiments of the present invention will become apparent from the following description, the accompanying drawings, and the appended claims.

### 7BRIEF DESCRIPTION OF THE DRAWINGS

For a better understanding of the present invention, as well as other aspects and further features thereof, reference is made to the following description which is to be used in conjunction with the accompanying drawings, where:

FIG. 1 is a is a schematic diagram illustrating a heating element in the form of a coating.

FIG. 2 is a schematic diagram illustrating different heating element patterns.

### DETAILED DESCRIPTION

It is well known that to make a heater of a given power (P) and voltage (V) you need a given resistance (R) as per equation (1).

$$P = \frac{{V}^{2}}{R} \qquad ( 1 )$$

The resistance (R) comprises a material component and a geometric component given by

$$R = \frac{( ρ \cdot L )}{( w \cdot t )} \qquad ( 2 )$$

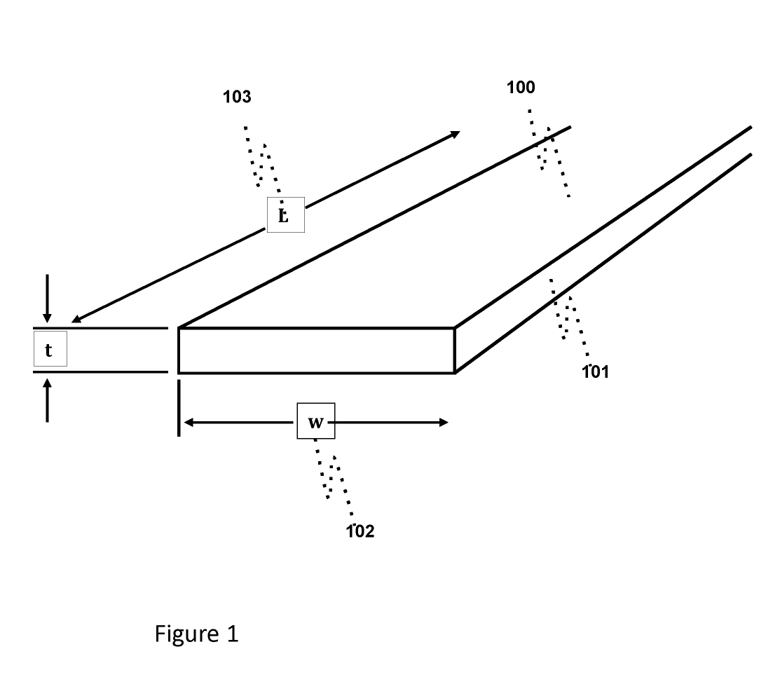

Referring to FIG. 1, which represents a portion of a deposited trace 100, ρ is the resistivity of the material used for the trace 100, t 101 is the trace thickness, w 102 is the trace width and L 103 is the trace length.

Therefore,

$$P = \frac{{V}^{2} \cdot ( w \cdot t )}{( ρ \cdot L )} \qquad ( 3 )$$

A heater of a required power (P) with a given voltage (V) can be built by varying one or more of the four parameters ρ, w, t and L.

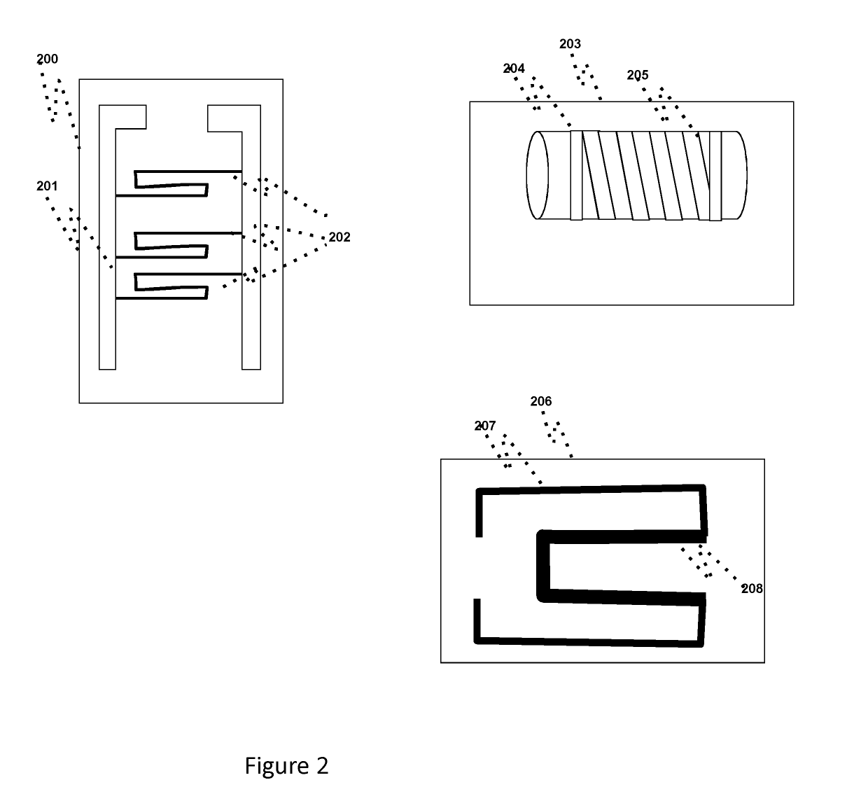

The heater is created by kinetic spraying the coating onto an electrically insulating substrate following a coating pattern specific to an application. FIG. 2 depicts different types of heating element coating patterns. The first example pattern 200 shows parallel heating elements 202 connected by a bus 201. The bus can be made of a less resistive material or is sometimes made wider and/or thicker to reduce the resistance and increase the current flow to all the elements. The second example 203, shows a heating element 205 coiled around a tube with buses 204 at both extremities. The third example 206 shows a pattern that provides non uniform power because the trace is narrower 207 at the edges delivering higher heat and wider in the middle 208 to deliver lower heat. The invention applies to any types of patterns, where the resistors are of any shape and placed in serial, parallel or combinations thereof and where any type of voltage can be applied.

As per equation (3) above, if the bulk resistivity of the material (ρ) can be increased, the geometric factors must adjust commensurately. In particular, L can be reduced such that the heater can be located on a smaller surface.

In one embodiment of the invention a fixed geometry (w, t and L) is assumed and the bulk resistivity of the material is adjusted by pre-oxidizing a metal powder, since metal oxides are typically electrically insulating, to achieve the required power and voltage. The metal powder can be pre-oxidized by heating the metal powder for a given time and temperature in air or another oxygen containing atmosphere to create an oxidized powder.

Another way of pre-oxidizing the metal powder is to thermal spray it in oxygen partial pressure, either in air or in a controlled environment with a predetermined amount of oxygen and then collecting the resultant oxidized powder.

The metal powder comprises one or more of copper, nickel, aluminum, titanium, nickel-chromium, nickel alloys, iron, iron-chromium-aluminum, iron alloys, tungsten, molybdenum, platinum or any other metal powder.

The oxidized powder can then be kinetic sprayed onto an electrically insulating substrate in a pattern so as to form a heating circuit (as per FIG. 2 or any other pattern). The resultant metal oxide molar fraction of the oxidized powder determines the bulk resistivity of the coating.

In another embodiment of this invention, the bulk resistivity of the heater coating can be increased by creating a ceramic-metal composite powder by coating ceramic powder particles with a proportion of metal to achieve a ceramic-metal composite with a predetermined bulk resistivity.

For example, a Chromium Carbide (CrC₂) powder particle can be coated with Nickel Chromium (NiCr) to increase the bulk resistivity of the resultant powder. Another example would consist of coating Tungsten Carbide (WC) with Cobalt (Co). Any other metal coating over ceramic particles that result in a high bulk resistivity could also be used. The ceramic-metal composite powder can then be kinetic sprayed onto an electrically insulating substrate in a pattern so as to form a circuit of resistors. The ratio of metal to ceramic in the ceramic-metal composite will dictate the bulk resistivity of the resulting coating following the well-known rule of mixtures.

In another embodiment of this invention, the bulk resistivity of the sprayed powder can be increased by agglomerating electrically insulating ceramic powder particles with a proportion of metal particles.

The agglomerated powder can then be kinetic sprayed onto an electrically insulating substrate in a pattern so as to form a heating circuit (as per FIG. 2). The resultant metal to ceramic proportion of the agglomerated powder determines the bulk resistivity of the sprayed coating.

Heating elements deposited as coatings on insulators as well as coatings deposited on conductive substrates may have mismatched coefficients of thermal expansion. It is desirable to match the thermal expansion coefficient of the substrate, the insulating layer and the heater to avoid generation of thermo-elastic stresses at material interfaces, which can cause delamination or cracking. The thermal expansion of the coating can be adjusted by mixing different metals with dissimilar thermal expansion coefficients to better match the thermal expansion coefficient of the substrate and the insulating layer.

In another embodiment of this invention, the geometric properties of the coating are designed to achieve a controlled resistance R assuming the resistivity (ρ) of the material is known and given that the kinetic spray process does not change the resistivity of the material. As per equation (3) above, if the bulk resistivity of the material (ρ) cannot be increased, the geometric factors can change and L can be reduced such that the heater can be located on a smaller surface. With kinetic spray, there is a range of thickness [tₘᵢₙ, tₘₐₓ] that can be achieved for a given material. If the coating is too thick it can delaminate and if it is too thin, the temperature achieved may not be uniform.

In general, a material with high resistivity that is commonly used for kinetic spray, would be used as a basis to make heater coatings, such as a Nickel Chromium (NiCr) alloy or Iron Chromium (FeCr) alloy, however any other metal powder that can be kinetic sprayed could be used.

By minimizing the width to wₘᵢₙ, within the constraint of the spraying system, a higher temperature can be achieved, but the geometry of the part and the thermal property of the substrate generally dictate the required width w_{req}.

Finally, the length (L) of the coating is maximized to fit within the constraints of the part where the heater is applied on a given pattern, and to take into account the possibly varying width required to achieve variable temperature.

Heater patterns may contain buses (such as element 204 and 201 in FIG. 2) to carry the current to one or more resistors, an advantage of using the cold spray is that a thicker deposit of the same resistive material can be used for the buses as compared to the thickness of the coating for the resistors. This can only be achieved using cold spray as it allows for thicker layers without risking delamination because of the compressive residual stresses. This greatly simplifies the coating process since only a single material needs to be applied.

It might be required to distribute the heat non-uniformly on the part in order to achieve desired temperature uniformity, in this case the width (w) can be modified in places along the path length to achieve the desired temperature. Element 206 of FIG. 2 shows a coating pattern that is deposited with varying width.

Modifications and improvements to the above-described embodiments of the present invention may become apparent to those skilled in the art. The foregoing description is intended to be exemplary rather than limiting. The scope of the present invention is therefore intended to be limited solely by the scope of the appended claims.

1. A method of fabricating a kinetic-sprayed resistor for use in a heater, comprising:
selecting a metal powder with a predetermined resistivity;
oxidizing the metal powder to create a predetermined molar fraction of metal oxide; and
kinetic spraying the oxidized metal powder in a pattern on an electrically-insulating substrate to create a resistive coating on the substrate in the pattern; and
coupling at least one electrical connectors to the resistive coating.

2. (canceled)

3. The method of claim 1, wherein the oxidizing of the metal powder is performed for a pre-determined length of time and at a pre-determined temperature.

4. The method of claim 1, wherein the metal powder comprises at least one metal selected from a group consisting of copper, nickel, titanium, aluminum, nickel-chromium, nickel alloys, iron, iron-chromium-aluminum, iron alloys, tungsten, molybdenum.

5. The method of claim 1, wherein the oxidizing includes thermally spraying the metal powder in an atmosphere having a partial pressure of oxygen.

6. The method of claim 5, wherein the partial pressure of oxygen in the atmosphere is controlled by having a predetermined amount of oxygen in the atmosphere.

7-10. (canceled)

11. A heater including the kinetic-sprayed resistor of claim 10, wherein the resistor is connectable to a power source to generate heat when electrical current runs through the resistor.

12. A method of fabricating a kinetic-sprayed resistor for use in a heater, comprising:
providing a mixture of ceramic powder and metal powder having a predetermined bulk resistivity; and
kinetic spraying the mixture of ceramic powder and metal powder in a pattern on an electrically-insulating substrate to create a resistive coating on the substrate in the pattern; and
coupling at least one electrical connectors to the resistive coating.

13. (canceled)

14. The method of claim 12, wherein the metal powder comprises at least one metal selected from a group consisting of CrC₂—NiCr and WC—Co.

15-18. (canceled)

19. A heater including the kinetic-sprayed resistor of claim 18, wherein the resistor is connectable to a power source to generate heat when electrical current runs through the resistor.

20. A method of fabricating a kinetic-sprayed resistor for use in a heater, comprising:
agglomerating an electrically-insulating powder and a metallic powder to create an agglomerated powder having a predetermined bulk resistivity; and
kinetic spraying the agglomerated powder in a pattern on a electrically-insulating substrate to create a resistive coating in the pattern on the substrate; and
coupling at least one electrical connectors to the resistive coating.

21. (canceled)

22. The method of claim 20, wherein the resistive coating sprayed in the pattern forms one selected from a group consisting of circuits in series, circuits in parallel, and a combination of circuits in series and circuits in parallel.

23. The method of claim 20, wherein at least one of a width and a height of the resistive coating sprayed in the pattern varies to result in power varying across the resistor when an electrical current is sent through the resistive coating.

24. The method of claim 20, wherein the pattern includes at least one bus and at least one of a width and a thickness of the resistive coating is greater at the bus.

25. (canceled)

26. A heater including the kinetic-sprayed resistor of claim 25, wherein the resistor is connectable to a power source to generate heat when electrical current runs through the resistor.

27. A method of fabricating a kinetic-sprayed resistor for use in a heater, wherein a predetermined amount of heat is generated when a predetermined electrical current at a predetermined voltage is passed through the resistor, the method comprising:
selecting (i) a metal powder having a resistivity between 10⁻⁶ Ohm-cm and 10⁻³ Ohm-cm and (ii) a pattern including a width, a length, and a thickness, such that when the metal powder is kinetically-sprayed in the pattern onto an electrically-insulating substrate, a coating layer is formed such that when the predetermined electrical current at the predetermined voltage is passed through the resistor the predetermined amount of heat is generated; and
kinetic spraying the metal powder in the pattern on the electrically-insulating substrate to create the resistive coating in the pattern on the substrate; and
coupling at least one electrical connector to the resistive coating.

28-30. (canceled)

31. The method of claim 27, wherein at least one of a width and a height of the resistive coating sprayed in the pattern varies to result in power varying across the resistor when an electrical current is sent through the resistive coating.

32. The method of claim 27, wherein the pattern includes at least one bus and at least one of a width and a height of the resistive coating is greater at the bus.

33. (canceled)

34. A heater including the kinetic-sprayed resistor of claim 27, wherein the resistor is connectable to a power source to generate heat when electrical current runs through the resistor.
